(19) United States
(12) Patent Application Publication
(10) Pub. No.: US 2026/0148694 A1
(43) Pub. Date: May 28, 2026

(54) VIEWING ANGLE SWITCHABLE DISPLAY DEVICE

(71) Applicant: LG Display Co., Ltd., Seoul (KR)

(72) Inventors: Young-Kyu SHIN, Paju-si (KR); Chang-Seok OH, Paju-si (KR); Yeon-Ji RYU, Paju-si (KR)

(73) Assignee: LG Display Co., Ltd., Seoul (KR)

(21) Appl. No.: 19/345,496

(22) Filed: Sep. 30, 2025

(30) Foreign Application Priority Data
Nov. 26, 2024 (KR) 10-2024-0171185

(51) Int. Cl. G09G 3/3233; G02B 3/06; H10K 59/80

(52) U.S. Cl. CPC G09G 3/3233; H10K 59/879; G02B 3/06; G09G 2300/0819; G09G 2300/0842; G09G 2300/0861; G09G 2310/08; G09G 2320/0233; G09G 2320/028

(57) ABSTRACT

A viewing angle switchable display device can include a first transistor connected to a second node, a second transistor connected to the second node and a fourth node, a third transistor connected to the fourth node and a fifth node, a fourth transistor connected to the fourth node and a sixth node, a fifth transistor connected to the first node and the second node, a sixth transistor connected to the fifth node, a seventh transistor connected to the sixth node, an eighth transistor connected to a third node, a ninth transistor connected to the third node, first and second light emitting diodes connected to the fifth node and the sixth node, a tenth transistor connected to the first and second light emitting diodes, and an eleventh transistor connected to the first and second light emitting diodes.

### CROSS-REFERENCE TO RELATED APPLICATION

The present application claims priority to Korean Patent Application No. 10-2024-0171185, filed in the Republic of Korea on Nov. 26, 2024, which is hereby incorporated by reference in its entirety.

### BACKGROUND

### Field of the Disclosure

The present disclosure relates to a display device, and more particularly, to a viewing angle switchable display device with improved features.

### Description of the Related Art

Recently, with the advent of an information-oriented society, the interest in information displays for processing and displaying a massive amount of information and the demand for portable information media have increased. Further, as a request for using a portable information media increases, various light and thin flat panel display devices have been developed and highlighted.

Among the various flat panel display devices, an organic light emitting diode (OLED) display device is an emissive type device that does not include a backlight unit used in a non-emissive type device such as a liquid crystal display (LCD) device. As a result, the OLED display device has advantages in a viewing angle, a contrast ratio and a power consumption to be applied to various fields.

Specifically, the OLED display device has been used for a dashboard of a vehicle. In a field of a vehicle, a viewing angle switchable OLED display device where a driver and a passenger selectively watch an image has been researched and developed.

In a viewing angle switchable OLED display device, since one subpixel is divided into an area for a light emitting diode of a wide viewing angle and an area for a light emitting diode of a narrow viewing angle, a capacitance of the light emitting diode can be reduced and the light emitting diode can emit a light even by a relatively low voltage. As a result, a luminance of a black can increase and a contrast ratio can be reduced.

### SUMMARY OF THE DISCLOSURE

Accordingly, the present disclosure is directed to a display device that substantially obviates one or more of the problems due to limitations and disadvantages of the related art.

More specifically, the present disclosure is to provide a viewing angle switchable display device where an emission of a light emitting diode during a period except for an emission period is prevented, an increase of a luminance of a black is prevented, and a contrast ratio is improved by connecting a selecting transistor to the light emitting diode and selectively applying a reference signal or a low level signal to the light emitting diode.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a viewing angle switchable display device includes a subpixel. The subpixel comprises a first transistor, the first transistor configured to switch according to a voltage of a first node and connected to a high level signal and a second node; a second transistor, the second transistor configured to switch according to a first emission signal and connected to the second node and a fourth node; a third transistor, the third transistor configured to switch according to a second emission signal and connected to the fourth node and a fifth node; a fourth transistor, the fourth transistor configured to switch according to a third emission signal and connected to the fourth node and a sixth node; a fifth transistor, the fifth transistor configured to switch according to a second scan signal and connected to the first node and the second node; a sixth transistor, the sixth transistor configured to switch according to the second scan signal and connected to the fifth node and a reference signal; a seventh transistor, the seventh transistor configured to switch according to the second scan signal and connected to the sixth node and the reference signal; an eighth transistor, the eighth transistor configured to switch according to the first emission signal and connected to a third node and the reference signal; a ninth transistor, the ninth transistor configured to switch according to a first scan signal and connected to the third node and a data signal; a first light emitting diode and a second light emitting diode respectively connected to the fifth node and the sixth node; a tenth transistor, the tenth transistor connected to at least one of the first and second light emitting diodes and the reference signal; and an eleventh transistor, the eleventh transistor connected to at least one of the first and second light emitting diodes and a low level signal.

It is to be understood that both the foregoing general description and the following detailed description are explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this disclosure, illustrate embodiments of the disclosure and together with the description serve to explain the principles of the disclosure.

In the drawings:

FIG. 1 is a view showing a viewing angle switchable display device according to a first embodiment of the present disclosure;

FIG. 2 is a circuit diagram showing an example of a subpixel of a viewing angle switchable display device according to the first embodiment of the present disclosure;

FIG. 3 is a view showing an example of a plurality of signals of a subpixel of a viewing angle switchable display device according to the first embodiment of the present disclosure;

FIGS. 4A to 4D are views showing an example of operation states of a subpixel of a viewing angle switchable display device according to the first embodiment of the present disclosure;

FIG. 5A is a view showing an example of first and second gate driving units of a viewing angle switchable display device according to the first embodiment of the present disclosure;

FIG. 5B is a view showing an example of a plurality of signals of a selection block of a viewing angle switchable display device according to the first embodiment of the present disclosure;

FIG. 5C is a view showing an example of input and output signals of a generating part of a selection block of a viewing angle switchable display device according to the first embodiment of the present disclosure;

FIG. 6A is a view showing an example of first and second gate driving units of a viewing angle switchable display device according to a second embodiment of the present disclosure; and

FIG. 6B is a view showing an example of a plurality of signals of a selection block of a viewing angle switchable display device according to the second embodiment of the present disclosure.

### DETAILED DESCRIPTION OF THE EMBODIMENTS

Advantages and features of the present disclosure, and implementation methods thereof will be clarified through following example aspects described with reference to the accompanying drawings. The present disclosure may, however, be embodied in different forms and should not be construed as limited to the example aspects set forth herein. Rather, these example aspects are provided so that this disclosure can be sufficiently thorough and complete to assist those skilled in the art to fully understand the scope of the present disclosure.

The shapes, sizes, ratios, angles, numbers, and the like, which are illustrated in the drawings to describe various example aspects of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration can unnecessarily obscure a feature or aspect of the present disclosure, a detailed description of such known function or configuration can be omitted or a brief description can be provided.

Where the terms such as “comprise,” “have,” “include,” and the like are used, one or more other elements can be added unless the term, such as “only,” is used. An element described in the singular form is intended to include a plurality of elements, and vice versa, unless the context clearly indicates otherwise. Further, the term “can” fully encompasses all the meanings and coverages of the term “may” and vice versa.

In construing an element, the element is to be construed as including an error or a tolerance range even where no explicit description of such an error or tolerance range is provided.

Where positional relationships are described, for example, where the positional relationship between two parts is described using terms such as “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third layer or element can be interposed therebetween.

Although the terms such as “first,” “second,” A, B, (a), (b), and the like can be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” can include all combinations of two or more of the first, second and third elements as well as the first, second or third element.

The term “display device” can include a display device in a narrow sense such as liquid crystal module (LCM), an organic light emitting diode (OLED) module and a quantum dot (QD) module including a display panel and a driving unit for driving the display panel. In addition, the term “display device” can include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure can include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit can be expressed as “a display device”, and an electronic apparatus of a complete product including the LCM, the OLED module and the QD module can be expressed as “a set device.” For example, a display device in a narrow sense can include a display panel of a liquid crystal, an organic light emitting diode and a quantum dot and a source printed circuit board (PCB) of a control unit for driving the display panel, and a set device can further include a set PCB of a set control unit electrically connected to the source PCB for controlling the entire set device.

The display panel of the present disclosure can include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel can include a plurality of gate lines, a plurality of data lines and a subpixel in a crossing region of the plurality of gate lines and the plurality of data lines. The display panel can include an array having a thin film transistor of an element for selectively applying a voltage to each subpixel, an emitting element layer on the array and an encapsulating substrate or an encapsulation part covering the emitting element layer. The encapsulation part can protect the thin film transistor and the emitting element layer from an external impact and can prevent or at least reduce penetration of a moisture or oxygen into the emitting element layer. In addition, the emitting element layer on the array can include an inorganic light emitting layer, for example, a nano-sized material layer or a quantum dot.

The thin film transistor of the present disclosure can include one of an oxide thin film transistor, an amorphous silicon thin film transistor, and a low temperature polycrystalline silicon thin film transistor.

Features of various embodiments of the present disclosure can be partially or entirely coupled to or combined with each other. They can be linked and operated technically in various ways as those skilled in the art can sufficiently understand. The aspects can be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings. All the components of each viewing angle switchable display device/apparatus according to all embodiments of the present disclosure are operatively coupled and configured.

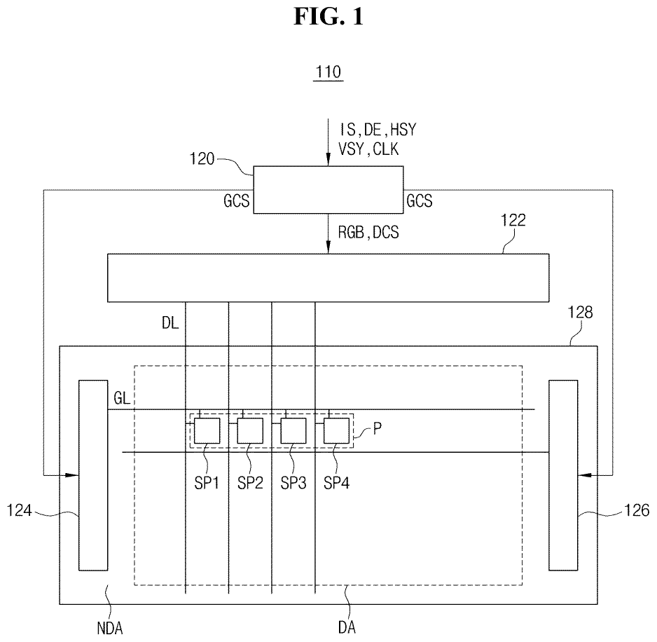

FIG. 1 is a view showing a viewing angle switchable display device according to a first embodiment of the present disclosure. Although the display device can be an organic light emitting diode (OLED) display device, it is not limited thereto. For example, the display device can be a quantum dot (QD) display device, a micro light emitting diode (LED) display device or a mini light emitting diode (LED) display device, or any other suitable display type.

Referring to FIG. 1, a viewing angle switchable display device 110 according to the first embodiment of the present disclosure includes a timing controlling unit 120 (e.g., a circuit), a data driving unit 122 (e.g., a circuit), first and second gate driving units 124 and 126 (e.g., circuits) and a display panel 128.

The timing controlling unit 120 generates an image data RGB, a data control signal DCS and a gate control signal GCS using an image signal IS and a plurality of timing signals including a data enable signal DE, a horizontal synchronization signal HSY, a vertical synchronization signal VSY and a clock signal CLK transmitted from an external system such as a graphic card or a television system.

The timing controlling unit 120 transmits the image data RGB and the data control signal DCS to the data driving unit 122 and transmits the gate control signal GCS to the first and second gate driving units 124 and 126.

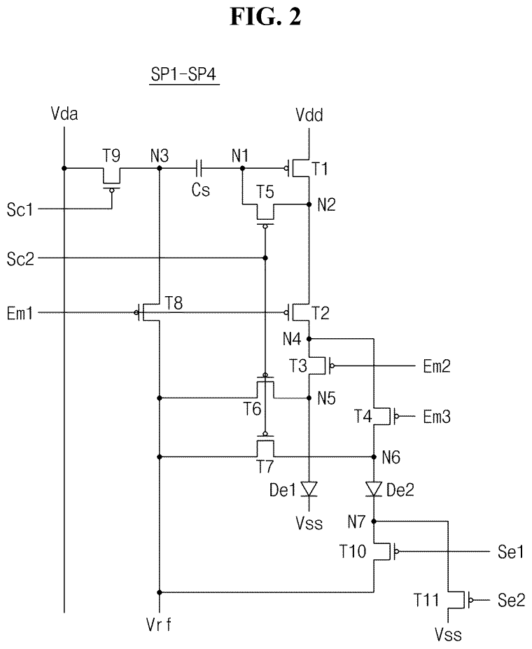

The data driving unit 122 generates a data signal (a data voltage) Vda (of FIG. 2) using the image data RGB and the data control signal DCS transmitted from the timing controlling unit 120 and applies the data signal Vda to a data line DL of the display panel 128.

The first and second gate driving units 124 and 126 generate a gate signal (a gate voltage) Sc1, Sc2, Em1, Em2, Em3, Se1 and Se2 (of FIG. 2) using the gate control signal GCS transmitted from the timing controlling unit 120 and applies the gate signal Sc1, Sc2, Em1, Em2, Em3, Se1 and Se2 to a gate line GL of the display panel 128.

The first and second gate driving units 124 and 126 can have a gate in panel (GIP) type to be formed in a non-display area NDA of a substrate of the display panel 128 having the gate line GL, the data line DL and a pixel P.

Although the first and second gate driving units 124 and 126 are disposed in both side portions of the display panel 128 in the first embodiment of FIG. 1, one gate driving unit can be disposed in one side portion of the display panel 128 in another embodiment of the present disclosure, or other types of arrangement for one or more gate driving units can be provided.

The display panel 128 includes a display area DA (or active area) at a central portion thereof and a non-display area NDA (or non-active area) surrounding the display area DA. The non-display area NDA can surround the display area DA entirely or only in part(s). The display panel 128 displays an image using the gate signal Sc1, Sc2, Em1, Em2, Em3, Se1 and Se2 and the data signal Vda. For displaying an image, the display panel 128 includes a plurality of pixels P, a plurality of gate lines GL and a plurality of data lines DL in the display area DA.

Each of the plurality of pixels P includes first, second, third and fourth subpixels SP1, SP2, SP3 and SP4. The gate line GL and the data line DL cross each other to define the first, second, third and fourth subpixels SP1, SP2, SP3 and SP4, and each of the first, second, third and fourth subpixels SP1, SP2, SP3 and SP4 is connected to the gate line GL and the data line DL.

For example, the first, second, third and fourth subpixels SP1, SP2, SP3 and SP4 can correspond to red, green, blue and white colors, respectively.

Although each pixel P as an example includes the first, second, third and fourth subpixels SP1, SP2, SP3 and SP4 in the first embodiment of FIG. 1, each pixel P can include first, second and third subpixels SP1, SP2 and SP3 corresponding to red, green and blue colors, respectively, in another embodiment of the present disclosure. In other examples, each pixel P can include a different color combination and arrangement of subpixels.

When the viewing angle switchable display device 110 is an organic light emitting diode (OLED) display device, each of the first, second, third and fourth subpixels SP1, SP2, SP3 and SP4 can include a plurality of transistors such as a switching transistor, a driving transistor and a sensing transistor, a storage capacitor and a light emitting diode.

A structure of the subpixel of the viewing angle switchable display device 110 according to one or more examples of the present disclosure will be discussed and illustrated with reference to the drawings.

FIG. 2 is a circuit diagram showing a subpixel of a viewing angle switchable display device according to the first embodiment of the present disclosure. Each subpixel of the display device of FIG. 1 can have the subpixel configuration of FIG. 1.

Referring to FIG. 2, each of the first, second, third and fourth subpixels SP1, SP2, SP3 and SP4 of the display panel 128 of the viewing angle switchable display device 110 according to the first embodiment of the present disclosure includes first to eleventh transistors T1 to T11, a storage capacitor Cs and first and second light emitting diodes De1 and De2.

Although the first to eleventh transistors T1 to T11 have a positive type in the first embodiment of FIG. 2, at least one of the first to eleventh transistors T1 to T11 can have a negative type in another embodiment of the present disclosure.

The first transistor T1 as a driving transistor is switched according to a voltage of a first node N1. A gate electrode of the first transistor T1 is connected to the first node N1, a source electrode of the first transistor T1 is connected to a high level signal (high level voltage) Vdd, and a drain electrode of the first transistor T1 is connected to a second node N2.

The second transistor T2 as an emitting transistor is switched according to a first emission signal Em1. A gate electrode of the second transistor T2 is connected to the first emission signal Em1, a source electrode of the second transistor T2 is connected to the second node N2, a drain electrode of the second transistor T2 is connected to a fourth node N4.

The third transistor T3 as an emission transistor is switched according to a second emission signal Em2. A gate electrode of the third transistor T3 is connected to the second emission signal Em2, a source electrode of the third transistor T3 is connected to the fourth node N4, and a drain electrode of the third transistor T3 is connected to a fifth node N5.

The fourth transistor T4 as an emission transistor is switched according to a third emission signal Em3. A gate electrode of the fourth transistor T4 is connected to the third emission signal Em3, a source electrode of the fourth transistor T4 is connected to the fourth node N4, and a drain electrode of the fourth transistor T4 is connected to a sixth node N6.

The fifth transistor T5 as a sensing transistor is switched according to a second scan signal Sc2. A gate electrode of the fifth transistor T5 is connected to the second scan signal Sc2, a source electrode of the fifth transistor T5 is connected to the second node N2, and a drain electrode of the fifth transistor T5 is connected to the first node N1.

The sixth transistor T6 is switched according to the second scan signal Sc2. A gate electrode of the sixth transistor T6 is connected to the second scan signal Sc2, a source electrode of the sixth transistor T6 is connected to the fifth node N5, and a drain electrode of the sixth transistor T6 is connected to a reference signal (reference voltage) Vrf.

The seventh transistor T7 is switched according to the second scan signal Sc2. A gate electrode of the seventh transistor T7 is connected to the second scan signal Sc2, a source electrode of the seventh transistor T7 is connected to the sixth node N6, and a drain electrode of the seventh transistor T7 is connected to the reference signal Vrf.

The eighth transistor T8 is switched according to the first emission signal Em1. A gate electrode of the eighth transistor T8 is connected to the first emission signal Em1, a source electrode of the eighth transistor T8 is connected to the third node N3, and a drain electrode of the eighth transistor T8 is connected to the reference signal Vrf.

The ninth transistor T9 as a switching transistor is switched according to the first scan signal Sc1. A gate electrode of the ninth transistor T9 is connected to the first scan signal Sc1, a source electrode of the ninth transistor T9 is connected to the third node N3, and a drain electrode of the ninth transistor T9 is connected to a data signal Vda.

The tenth transistor T10 as a selecting transistor is switched according to a first selection signal Se1. A gate electrode of the tenth transistor T10 is connected to the first selection signal Se1, a source electrode of the tenth transistor T10 is connected to a seventh node N7, and a drain electrode of the tenth transistor T10 is connected to the reference signal Vrf.

The eleventh transistor T11 as a selecting transistor is switched according to a second selection signal Se2. A gate electrode of the eleventh transistor T11 is connected to the second selection signal Se2, a source electrode of the eleventh transistor T11 is connected to the seventh node N7, and a drain electrode of the eleventh transistor T11 is connected to a low level signal (low level voltage) Vss.

For example, the first selection signal Se1 and the second selection signal Se2 can be inverted signals from each other.

The storage capacitor Cs stores the data signal Vda and a threshold voltage (Vth) of the first transistor T1. A first capacitor electrode of the storage capacitor Cs is connected to the first node N1, and a second capacitor electrode of the storage capacitor Cs is connected to the third node N3.

The first light emitting diode De1 is connected between the fifth node N5 and the low level signal (low level voltage) Vss and emits a light of a luminance proportional to a current of the first transistor T1. An anode of the first light emitting diode De1 is connected to the fifth node N5, and a cathode of the first light emitting diode De1 is connected to the low level signal Vss.

The second light emitting diode De2 is connected between the sixth and seventh nodes N6 and N7 and emits a light of a luminance proportional to a current of the first transistor T1. An anode of the second light emitting diode De2 is connected to the sixth node N6, and a cathode of the second light emitting diode De2 is connected to the seventh node N7.

A hemicylindrical lens focusing a light along up and down directions and not focusing a light along left and right directions is disposed on the first light emitting diode De1 to display an image of a wide viewing angle to left and right users, and a hemispherical lens focusing a light along up, down, left and right directions is disposed on the second light emitting diode De2 to display an image of a narrow viewing angle to one of left and right users.

The gate electrode of the first transistor T1, the first capacitor electrode of the storage capacitor Cs and the drain electrode of the fifth transistor T5 constitute the first node N1, and the drain electrode of the first transistor T1, the source electrode of the second transistor T2 and the source electrode of the fifth transistor T5 constitute the second node N2. The second capacitor electrode of the storage capacitor Cs, the source electrode of the eighth transistor T8 and the source electrode of the ninth transistor T9 constitute the third node N3, and the drain electrode of the second transistor T2, the source electrode of the third transistor T3 and the source electrode of the fourth transistor T4 constitute the fourth node N4. The drain electrode of the third transistor T3, the source electrode of the sixth transistor T6 and the anode of the first light emitting diode De1 constitute the fifth node N5, and the drain electrode of the fourth transistor T4, the source electrode of the seventh transistor T7 and the anode of the second light emitting diode De2 constitute the sixth node N6. The cathode of the second light emitting diode De2, the source electrode of the tenth transistor T10 and the source electrode of the eleventh transistor T11 constitute the seventh node N7.

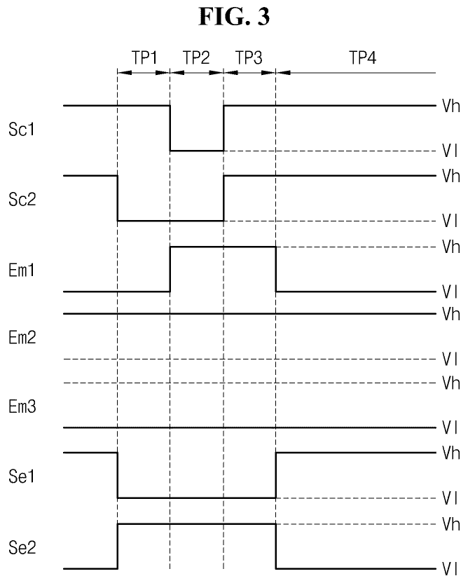

In the viewing angle switchable display device 110 according to the first embodiment of the present disclosure, the tenth and eleventh transistors T10 and T11 switched according to the first selection signal Se1 and the second selection signal Se2, respectively, are connected to the cathode of the second light emitting diode De2, and the tenth transistor T10 is turned on during a first period TP1 (of FIG. 3) as an initializing period, a second period TP2 (of FIG. 3) as a sampling period and a third period TP3 (of FIG. 3) as a holding period to connect the cathode of the second light emitting diode De2 to the reference signal Vrf. Since the anode and the cathode of the second light emitting diode De2 have the same potential as each other, an emission of the second light emitting diode De2 is prevented, and an increase of a luminance of a black is prevented.

Further, the eleventh transistor T11 is turned on during a fourth period TP4 (of FIG. 3) as an emitting period to connect the cathode of the second light emitting diode De2 to the low level signal Vss. As a result, the second light emitting diode De2 emits a light of a luminance corresponding to the data signal Vda to display an image of a narrow viewing angle.

Although one subpixel has a 11T1C structure having eleven transistors and one storage capacitor in the first embodiment of FIG. 2, one subpixel can have one of a 8T1C structure having eight transistors and one storage capacitor, a 12T1C structure having twelve transistors and one storage capacitor and a 13T1C structure having thirteen transistors and one storage capacitor in another embodiment of the present disclosure.

Although the tenth and eleventh transistors T10 and T11 are exemplarily connected to the second light emitting diode De2 in the first embodiment of FIG. 2, the tenth and eleventh transistors T10 and T11 can be connected to each of the first and second light emitting diodes De1 and De2 to prevent an abnormal emission, or the tenth and eleventh transistors T10 and T11 can be connected to the first light emitting diode De1 to prevent an abnormal emission of the first light emitting diode De1 in another embodiment of the present disclosure.

An operation of the subpixel of the viewing angle switchable display device 110 according to one or more examples of the present disclosure will be discussed and illustrated with reference to the drawings.

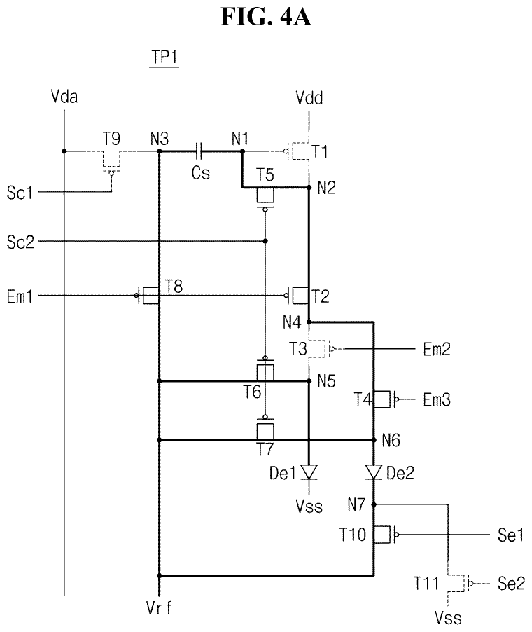

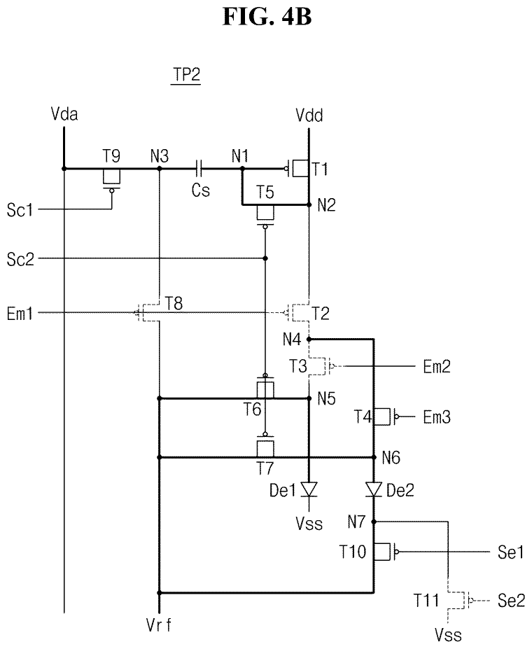

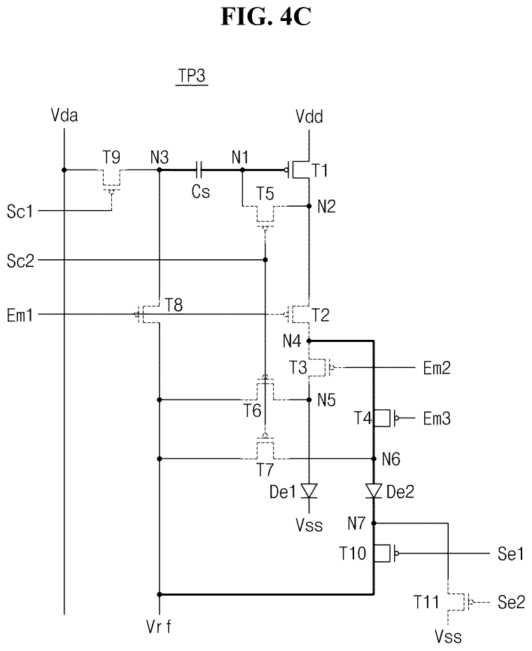

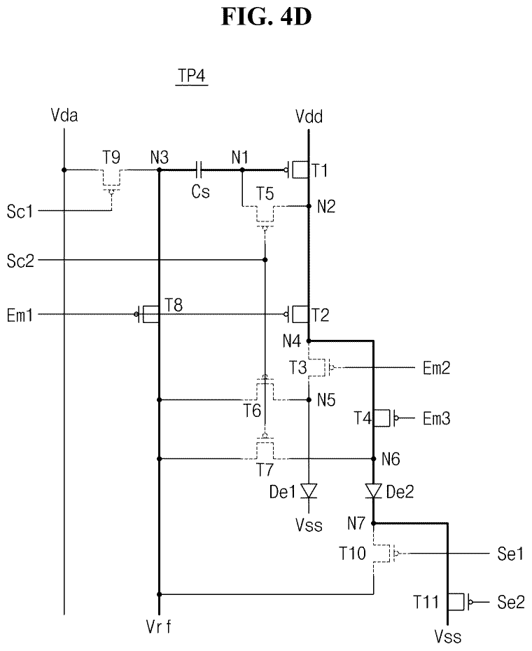

FIG. 3 is a view showing a plurality of signals of a subpixel of a viewing angle switchable display device according to the first embodiment of the present disclosure, and FIGS. 4A to 4D are views showing operation states of a subpixel of a viewing angle switchable display device according to the first embodiment of the present disclosure. These figures show examples of the operations of the display device of FIGS. 1 and 2.

Referring to FIG. 3, each of the first, second, third and fourth subpixels SP1, SP2, SP3 and SP4 of the viewing angle switchable display device 110 according to the first embodiment of the present disclosure is driven through first to fourth periods TP1 to TP4.

Referring to FIGS. 3 and 4A, during a first period TP1 as an initializing period, the second, fifth, sixth, seventh, eighth and tenth transistors T2, T5, T6, T7, T8 and T10 are turned on due to (e.g., in response to) the second scan signal Sc2, the first emission signal Em1, the third emission signal Em3 and the first selection signal Se1 of a logic low voltage Vl, and the third, ninth and eleventh transistors T3, T9 and T11 are turned off due to (e.g., in response to) the first scan signal Sc1, the second emission signal Em2 and the second selection signal Se2 of a logic high voltage Vh. Since the reference signal Vrf is applied to the first, second, third, fourth, fifth, sixth and seventh nodes N1, N2, N3, N4, N5, N6 and N7, the first transistor T1 is turned off and the first and second capacitor electrodes of the storage capacitor Cs, the gate electrode of the first transistor T1, the anode of the first light emitting diode De1 and the anode and the cathode of the second light emitting diode De2 are initialized by the reference signal Vrf.

Here, the reference signal Vrf is applied to the anode and the cathode of the second light emitting diode De2 to prevent an emission of the second light emitting diode De2.

Referring to FIGS. 3 and 4B, during the second period TP2 as a sampling period, the fourth, fifth, sixth, seventh, ninth and tenth transistors T4, T5, T6, T7, T9 and T10 are turned on due to (e.g., in response to) the first scan signal Sc1, the second scan signal Sc2, the third emission signal Em3 and the first selection signal Se1 of a logic low voltage Vl, and the second, third, eighth and eleventh transistors T2, T3, T8 and T11 are turned off due to (e.g., in response to) the first emission signal Em1, the second emission signal Em2 and the second selection signal Se2 of a logic high voltage Vh. The data signal Vda is applied to the third node N3, and the reference signal Vrf is applied to the fifth, sixth and seventh nodes N5, N6 and N7. As a result, the first transistor T1 is turned on, the second capacitor electrode of the storage capacitor Cs has the data signal Vda, and the first capacitor electrode of the storage capacitor Cs has a sum of a difference between the data signal Vda and the reference signal Vrf and the threshold voltage Vth (Vda−Vrf+Vth). Accordingly, the threshold voltage Vth is stored in the storage capacitor Cs, and the anode of the first light emitting diode De1 and the anode and the cathode of the second light emitting diode De2 are kept as the reference signal Vrf.

Referring to FIGS. 3 and 4C, during the third period TP3 as a holding period, the fourth and tenth transistors T4 and T10 are turned on due to (e.g., in response to) the third emission signal Em3 and the first selection signal Se1 of a logic low voltage Vl, and the second, third, fifth, sixth, seventh, eighth, ninth and eleventh transistors T2, T3, T5, T6, T7, T8, T9 and T11 are turned off due to (e.g., in response to) the first scan signal Sc1, the second scan signal Sc2, the first emission signal Em1, the second emission signal Em2 and the second selection signal Se2 of a logic high voltage Vh. As a result, the reference signal Vrf is applied to the seventh node N7, the second capacitor electrode of the storage capacitor Cs is kept as the data signal Vda, and the first capacitor electrode of the storage capacitor Cs is kept as a sum (Vda−Vrf+Vth) of a difference between the data signal Vda and the reference signal Vrf and the threshold voltage Vth. Accordingly, the threshold voltage Vth is kept to be stored in the storage capacitor Cs, and the anode and the cathode of the second light emitting diode De2 are kept as the reference signal Vrf.

Referring to FIGS. 3 and 4D, during the fourth period TP4 as an emission period, the second, fourth, eighth and eleventh transistors T2, T4, T8 and T11 are turned on due to (e.g., in response to) the first emission signal Em1, the third emission signal Em3 and the second selection signal Se2 of a logic low voltage Vl, and the third, fifth, sixth, seventh, ninth and tenth transistors T3, T5, T6, T7, T9 and T10 are turned off due to (e.g., in response to) the first scan signal Sc1, the second scan signal Sc2, the second emission signal Em2 and the first selection signal Se1 of a logic high voltage Vh. As a result, the reference signal Vrf is applied to the third node N3, a current proportional to a square of a value ((Vda−Vrf+Vth−Vdd)−Vth=Vda−Vrf−Vdd) obtained by subtracting the threshold voltage Vth from a gate-source voltage Vgs flows through the first transistor T1, and the second light emitting diode De2 emits a light of a luminance corresponding to the current flowing through the first transistor T1.

In the viewing angle switchable display device 110 according to the first embodiment of the present disclosure, the tenth transistor T10 connected to the reference signal Vrf and the eleventh transistor T11 connected to the low level signal Vss are connected to the cathode of at least one of the first and second light emitting diodes De1 and De2, and the reference signal Vrf is supplied to the cathode of the at least one of the first and second light emitting diodes De1 and De2 during the first, second and third periods TP1, TP2 and TP3 corresponding to the initializing period, the sampling period and the holding period. Since the emission of the at least one of the first and second light emitting diodes De1 and De2 is prevented, the increase of the luminance of the black is prevented and the contrast ratio is improved.

During the fourth period TP4 corresponding to the emitting period, since the low level signal Vss is supplied to the cathode of the at least one of the first and second light emitting diodes De1 and De2, the at least one of the first and second light emitting diodes De1 and De2 can emit a light normally.

Generation of the first selection signal Se1 and the second selection signal Se2 in the first and second gate driving units 124 and 126 of the viewing angle switchable display device 110 according to examples of the present disclosure will be illustrated and discussed with reference to the drawings.

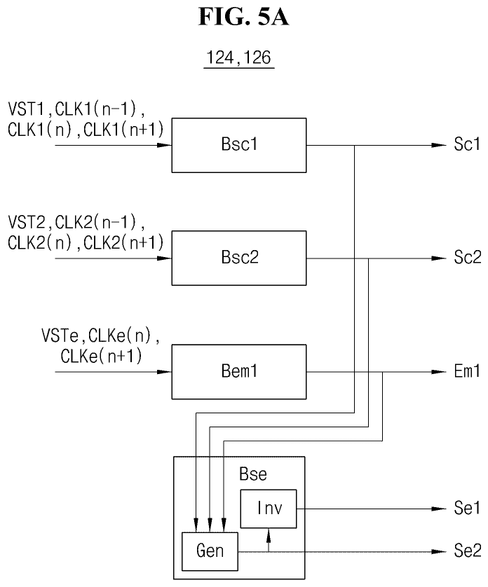

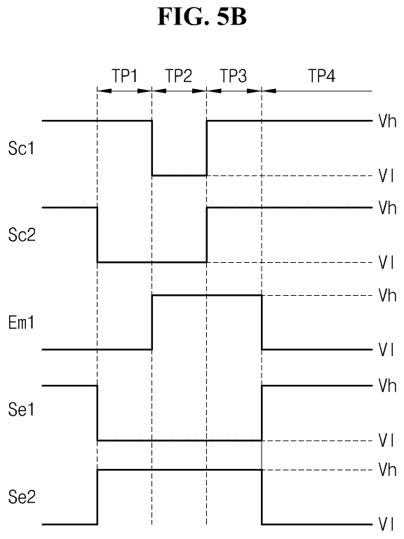

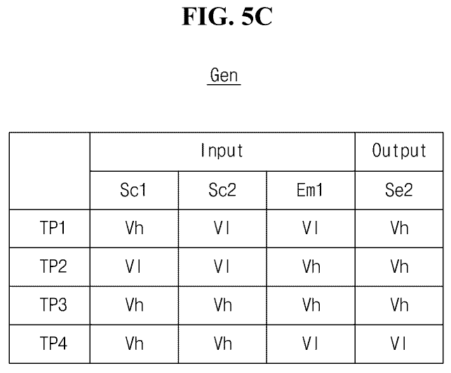

FIG. 5A is a view showing first and second gate driving units of a viewing angle switchable display device according to the first embodiment of the present disclosure, FIG. 5B is a view showing a plurality of signals of a selection block of a viewing angle switchable display device according to the first embodiment of the present disclosure, and FIG. 5C is a view showing input and output signals of a generating part of a selection block of a viewing angle switchable display device according to the first embodiment of the present disclosure. A “block” can include or be a circuit, module, unit, part, etc.

Referring to FIG. 5A, at least one of the first and second gate driving units 124 and 126 of the viewing angle switchable display device 110 according to the first embodiment of the present disclosure includes a first scan block Bsc1, a second scan block Bsc2, a first emission block Bem1 and a selection block Bse.

The first scan block Bsc1 generates the first scan signal Sc1 using a first start signal VST1, an (n−1)th first clock signal CLK1(n−1), an (n)th first clock signal CLK1(n) and an (n+1)th first clock signal CLK1(n+1) and transmits the first scan signal Sc1 to the display panel 128 and the selection block Bse. Here, n is a real number such as a positive integer.

The second scan block Bsc2 generates the second scan signal Sc2 using a start2 signal VST2, an (n−1)th second clock signal CLK2(n−1), an (n)th second clock signal CLK2(n) and an (n+1)th second clock signal CLK2(n+1) and transmits the second scan signal Sc2 to the display panel 128 and the selection block Bse.

In another embodiment of the present disclosure, the (n−1)th second clock signal CLK2(n−1), the (n)th second clock signal CLK2(n) and the (n+1)th second clock signal CLK2(n+1) can be the same as the (n−1)th first clock signal CLK1(n−1), the (n)th first clock signal CLK1(n) and the (n+1)th first clock signal CLK1(n+1), respectively.

The first emission block Bem1 generates the first emission signal Em1 using an emission start signal VSTe, an (n)th emission clock signal CLKe(n) and an (n+1)th emission clock signal CLKe(n+1) and transmits the first emission signal Em1 to the display panel 128 and the selection block Bse.

In another embodiment of the present disclosure, the (n)th emission clock signal CLKe(n) and the (n+1)th emission clock signal CLKe(n+1) can be the same as the first first clock signal CLK1(1) and the second first clock signal CLK1(2), respectively.

The selection block Bse generates the first selection signal Se1 and the second selection signal Se2 using the first scan signal Sc1, the second scan signal Sc2 and the first emission signal Em1 and transmits the first selection signal Se1 and the second selection signal Se2 to the display panel 128.

The selection block Bse includes a generating part Gen generating the second selection signal Se2 using the first scan signal Sc1, the second scan signal Sc2 and the first emission signal Em1 and an inverting part Inv generating the first selection signal Se1 using the second selection signal Se2.

For example, the first selection signal Se1 and the second selection signal Se2 can be inverted signals from each other, and the inverting part Inv can be an inverter.

At least one of the first and second gate driving units 124 and 126 can further include a second emission block generating the second emission signal Em2 and a third emission block generating the third emission signal Em3.

Referring to FIGS. 5B and 5C, during the first period TP1, the generating part Gen receives the first scan signal Sc1 of a logic high voltage Vh, the second scan signal Sc2 of a logic low voltage Vl and the first emission signal Em1 of a logic low voltage Vl and outputs the second selection signal Se2 of a logic high voltage Vh. The inverting part Inv receives the second selection signal Se2 of a logic high voltage Vh and outputs the first selection signal Se1 of a logic low voltage Vl.

During the second period TP2, the generating part Gen receives the first scan signal Sc1 of a logic low voltage Vl, the second scan signal Sc2 of a logic low voltage Vl and the first emission signal Em1 of a logic high voltage Vh and outputs the second selection signal Se2 of a logic high voltage Vh. The inverting part Inv receives the second selection signal Se2 of a logic high voltage Vh and outputs the first selection signal Se1 of a logic low voltage Vl.

During the third period TP3, the generating part Gen receives the first scan signal Sc1 of a logic high voltage Vh, the second scan signal Sc2 of a logic high voltage Vh and the first emission signal Em1 of a logic high voltage Vh and outputs the second selection signal Se2 of a logic high voltage Vh. The inverting part Inv receives the second selection signal Se2 of a logic high voltage Vh and outputs the first selection signal Se1 of a logic low voltage Vl.

During the fourth period TP4, the generating part Gen receives the first scan signal Sc1 of a logic high voltage Vh, the second scan signal Sc2 of a logic high voltage Vh and the first emission signal Em1 of a logic low voltage Vl and outputs the second selection signal Se2 of a logic low voltage Vl. The inverting part Inv receives the second selection signal Se2 of a logic low voltage Vl and outputs the first selection signal Se1 of a logic high voltage Vh.

In the viewing angle switchable display device 110 according to the first embodiment of the present disclosure, the generating part Gen of the selection block Bse of the first and second gate driving units 124 and 126 can generate the second selection signal Se2 using the first scan signal Sc1, the second scan signal Sc2 and the first emission signal Em1, and the inverting part Inv of the selection block Bse of the first and second gate driving units 124 and 126 can generate the first selection signal Se1 by inverting the second selection signal Se2.

In another embodiment of the present disclosure, the first selection signal Se1 and the second selection signal Se2 can be generated using an additional selection start signal and an additional selection clock signal.

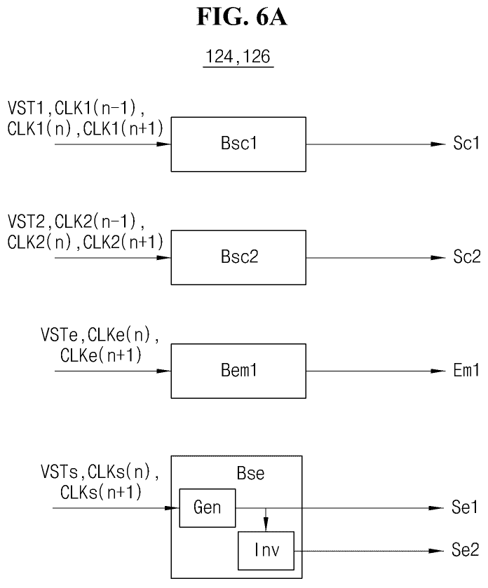

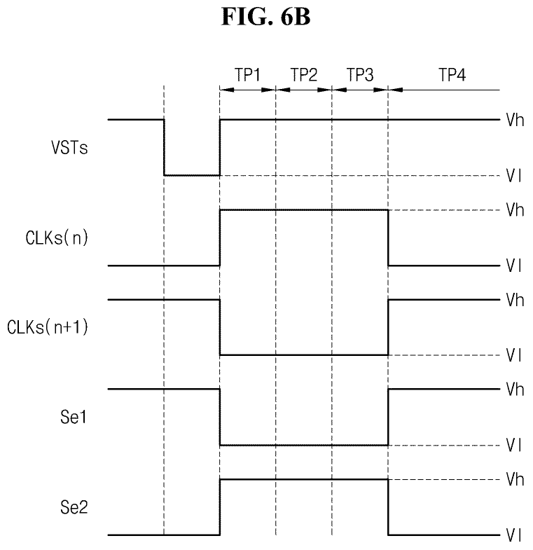

FIG. 6A is a view showing first and second gate driving units of a viewing angle switchable display device according to a second embodiment of the present disclosure, and FIG. 6B is a view showing a plurality of signals of a selection block of a viewing angle switchable display device according to the second embodiment of the present disclosure. Illustration on parts of the second embodiment that are the same as those of the first embodiment of the present disclosure can be omitted. For example, a general configuration of the display device of the first embodiment can be used in the second embodiment while the operations and related configurations may differ.

Referring to FIG. 6A, at least one of first and second gate driving units 124 and 126 of a viewing angle switchable display device 110 according to the second embodiment of the present disclosure includes a first scan block Bsc1, a second scan block Bsc2, a first emission block Bem1 and a selection block Bse.

The first scan block Bsc1 generates a first scan signal Sc1 using a first start signal VST1, an (n−1)th first clock signal CLK1(n−1), an (n)th first clock signal CLK1(n) and an (n+1)th first clock signal CLK1(n+1) and transmits the first scan signal Sc1 to a display panel 128. In all the examples, n is a real number such as a positive integer.

The second scan block Bsc2 generates the second scan signal Sc2 using a start2 signal VST2, an (n−1)th second clock signal CLK2(n−1), an (n)th second clock signal CLK2(n) and an (n+1)th second clock signal CLK2(n+1) and transmits the second scan signal Sc2 to the display panel 128.

In another embodiment of the present disclosure, the (n−1)th second clock signal CLK2(n−1), the (n)th second clock signal CLK2(n) and the (n+1)th second clock signal CLK2(n+1) can be the same as the (n−1)th first clock signal CLK1(n−1), the (n)th first clock signal CLK1(n) and the (n+1)th first clock signal CLK1(n+1), respectively.

The first emission block Bem1 generates the first emission signal Em1 using an emission start signal VSTe, an (n)th emission clock signal CLKe(n) and an (n+1)th emission clock signal CLKe(n+1) and transmits the first emission signal Em1 to the display panel 128.

In another embodiment of the present disclosure, the (n)th emission clock signal CLKe(n) and the (n+1)th emission clock signal CLKe(n+1) can be the same as the first first clock signal CLK1(1) and the second first clock signal CLK1(2), respectively.

The selection block Bse generates the first selection signal Se1 and the second selection signal Se2 using the selection start signal VSTs, the (n)th selection clock signal CLKs(n) and the (n+1)th selection clock signal CLK(n+1) and transmits the first selection signal Se1 and the second selection signal Se2 to the display panel 128.

The selection block Bse includes a generating part Gen generating the first selection signal Se1 using the selection start signal VSTs, the (n)th selection clock signal CLKs(n) and the (n+1)th selection clock signal CLK(n+1) and an inverting part Inv generating the second selection signal Se2 using the first selection signal Se1.

For example, the first selection signal Se1 and the second selection signal Se2 can be inverted signals from each other, and the inverting part Inv can be an inverter.

At least one of the first and second gate driving units 124 and 126 can further include a second emission block generating the second emission signal Em2 and a third emission block generating the third emission signal Em3.

Referring to FIG. 6B, a rising timing of the (n)th selection clock signal CLKs(n) and a falling timing of the (n+1)th selection clock signal CLKs(n+1) are synchronized to a rising timing of the selection start signal VSTs.

During the first period TP1, the generating part Gen receives the selection start signal VSTs of a logic high voltage Vh, the (n)th selection signal CLKs(n) of a logic high voltage Vh and the (n+1)th selection clock signal CLKs(n+1) of a logic low voltage Vl and outputs the first selection signal Se1 of a logic low voltage Vl. The inverting part Inv receives the first selection signal Se1 of a logic low voltage Vl and outputs the second selection signal Se2 of a logic high voltage Vh.

During the second period TP2, the generating part Gen receives the selection start signal VSTs of a logic high voltage Vh, the (n)th selection clock signal CLKs(n) of a logic high voltage Vh and the (n+1)th selection clock signal CLKs(n+1) of a logic low voltage Vl and outputs the first selection signal Se1 of a logic low voltage Vl. The inverting part Inv receives the first selection signal Se1 of a logic low voltage Vl and outputs the second selection signal Se2 of a logic high voltage Vh.

During the third period TP3, the generating part Gen receives the selection start signal VSTs of a logic high voltage Vh, the (n)th selection clock signal CLKs(n) of a logic high voltage Vh and the (n+1) selection clock signal CLKs(n+1) of a logic low voltage Vl and outputs the first selection signal Se1 of a logic low voltage Vl. The inverting part Inv receives the first selection signal Se1 of a logic low voltage Vl and outputs the second selection signal Se2 of a logic high voltage Vh.

During the fourth period TP4, the generating part Gen receives the selection start signal VSTs of a logic high voltage Vh, the (n)th selection clock signal CLKs(n) of a logic low voltage Vl and the (n+1)th selection clock signal CLKs(n+1) of a logic high voltage Vh and outputs the first selection signal Se1 of a logic high voltage Vh. The inverting part Inv receives the first selection signal Se1 of a logic high voltage Vh and outputs the second selection signal Se2 of a logic low voltage Vl.

In the viewing angle switchable display device 110 according to the second embodiment of the present disclosure, the generating part Gen of the selection block Bse of the first and second gate driving units 124 and 126 can generate the first selection signal Se1 using the selection start signal VSTs, the (n)th selection clock signal CLKs(n) and the (n+1)th selection clock signal CLKs(n+1), and the inverting part Inv of the selection block Bse of the first and second gate driving units 124 and 126 can generate the second selection signal Se2 by inverting the first selection signal Se1.

Accordingly, in the viewing angle switchable display device according to aspects of the present disclosure, since the reference signal Vrf is supplied to the cathode of at least one of the first and second light emitting diodes De1 and De2 during the initializing period, the sampling period and the holding period, emission of at least one of the first and second light emitting diodes De1 and De2 is prevented, increase of the luminance of the black is prevented, and the contrast ratio is improved. Further, since the low level signal Vss is supplied to the cathode of at least one of the first and second light emitting diodes De1 and De2 during the emitting period, at least one of the first and second light emitting diodes De1 and De2 emits a light normally.

It will be apparent to those skilled in the art that various modifications and variation can be made in the present disclosure without departing from the scope of the disclosure. Thus, it is intended that the present disclosure cover the modifications and variations of this disclosure provided they come within the scope of the appended claims and their equivalents.

What is claimed is:

1. A viewing angle switchable display device, comprising:
a plurality of subpixels disposed on a substrate,
wherein each of at least one of the plurality of subpixels comprises:
a first transistor configured to switch according to a voltage of a first node and connected to a high level signal and a second node;
a second transistor configured to switch according to a first emission signal and connected to the second node and a fourth node;
a third transistor configured to switch according to a second emission signal and connected to the fourth node and a fifth node;
a fourth transistor configured to switch according to a third emission signal and connected to the fourth node and a sixth node;
a fifth transistor configured to switch according to a second scan signal and connected to the first node and the second node;
a sixth transistor configured to switch according to the second scan signal and connected to the fifth node and a reference signal;
a seventh transistor configured to switch according to the second scan signal and connected to the sixth node and the reference signal;
an eighth transistor configured to switch according to the first emission signal and connected to a third node and the reference signal;
a ninth transistor configured to switch according to a first scan signal and connected to the third node and a data signal;
a first light emitting diode and a second light emitting diode respectively connected to the fifth node and the sixth node;
a tenth transistor connected to at least one of the first and second light emitting diodes and the reference signal; and
an eleventh transistor connected to at least one of the first and second light emitting diodes and a low level signal.

2. The viewing angle switchable display device of claim 1, wherein the tenth transistor and the eleventh transistor are configured to switch according to a first selection signal and a second selection signal, respectively.

3. The viewing angle switchable display device of claim 2, wherein the first selection signal and the second selection signal are inverted signals from each other.

4. The viewing angle switchable display device of claim 2, further comprising a selection block including:
a generating part configured to generate the second selection signal using the first scan signal, the second scan signal and the first emission signal, and
an inverting part configured to generate the first selection signal using the second selection signal.

5. The viewing angle switchable display device of claim 2, further comprising a selection block including:
a generating part configured to generate the first selection signal using a selection start signal, an (n)th selection clock signal and an (n+1)th selection clock signal, where n is a real number, and
an inverting part configured to generate the second selection signal using the first selection signal.

6. The viewing angle switchable display device of claim 1, further comprising a storage capacitor in the subpixel, the storage capacitor connected between the first node and the third node.

7. The viewing angle switchable display device of claim 6, wherein a gate electrode of the first transistor, a first capacitor electrode of the storage capacitor and a drain electrode of the fifth transistor constitute the first node,
wherein a drain electrode of the first transistor, a source electrode of the second transistor and a source electrode of the fifth transistor constitute the second node, and
wherein a second capacitor electrode of the storage capacitor, a source electrode of the eighth transistor and a source electrode of the ninth transistor constitute the third node.

8. The viewing angle switchable display device of claim 7, wherein a drain electrode of the second transistor, a source electrode of the third transistor and a source electrode of the fourth transistor constitute the fourth node,
wherein a drain electrode of the third transistor, a source electrode of the sixth transistor and an anode of the first light emitting diode constitute the fifth node, and
wherein a drain electrode of the fourth transistor, a source electrode of the seventh transistor and an anode of the second light emitting diode constitute the sixth node.

9. The viewing angle switchable display device of claim 2, wherein the first light emitting diode is connected between the fifth node and the low level signal,
wherein the second light emitting diode is connected between the sixth node and a seventh node, and
wherein a cathode of the second light emitting diode, a source electrode of the tenth transistor and a source electrode of the eleventh transistor constitute the seventh node.

10. The viewing angle switchable display device of claim 9, wherein, during a first period,
the second, fifth, sixth, seventh, eighth and tenth transistors are configured to turn on in response to the second scan signal, the first emission signal, the third emission signal and the first selection signal of a logic low voltage, and
the third, ninth and eleventh transistors are configured to turn off in response to the first scan signal, the second emission signal and the second selection signal of a logic high voltage.

11. The viewing angle switchable display device of claim 10, wherein, during a second period,
the fourth, fifth, sixth, seventh, ninth and tenth transistors are configured to turn on in response to the first scan signal, the second scan signal, the third emission signal and the first selection signal of a logic low voltage, and
the second, third, eighth and eleventh transistors are configured to turn off in response to the first emission signal, the second emission signal and the second selection signal of a logic high voltage.

12. The viewing angle switchable display device of claim 11, wherein, during a third period,
the fourth and tenth transistors are configured to turn on in response to the third emission signal and the first selection signal of a logic low voltage, and
the second, third, fifth, sixth, seventh, eighth, ninth and eleventh transistors are configured to turn off in response to the first scan signal, the second scan signal, the first emission signal, the second emission signal and the second selection signal of a logic high voltage.

13. The viewing angle switchable display device of claim 12, wherein, during a fourth period,
the second, fourth, eighth and eleventh transistors are configured to turn on in response to the first emission signal, the third emission signal and the second selection signal of a logic low voltage, and
the third, fifth, sixth, seventh, ninth and tenth transistors are configured to turn off in response to the first scan signal, the second scan signal, the second emission signal and the first selection signal of a logic high voltage.

14. The viewing angle switchable display device of claim 13, wherein the reference signal is applied to a cathode of the second light emitting diode during the first period, the second period and the third period, and
wherein the low level signal is applied to the cathode of the second light emitting diode during the fourth period.

15. The viewing angle switchable display device of claim 9, further comprising:
a first lens focusing a light along up and down directions and disposed over the first light emitting diode; and
a second lens focusing a light along up, down, left and right directions and disposed over the second light emitting diode.

16. The viewing angle switchable display device of claim 15, wherein the first lens is a hemicylindrical lens and the second lens is a hemispherical lens.

17. The viewing angle switchable display device of claim 1, further comprising a display panel including a display area having the plurality of subpixels.

18. The viewing angle switchable display device of claim 17, wherein the display panel further includes a non-display area at a periphery of the display area.
